(19) United States
(12) Patent Application Publication
(10) Pub. No.: US 2007/0235319 A1
(43) Pub. Date: Oct. 11, 2007

(54) MULTI-PROCESSING USING AN IONIZED PHYSICAL VAPOR DEPOSITION (IPVD) SYSTEM

(75) Inventor: Frank M. Cerio JR., Schenectady, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited, Tokyo (JP)

(21) Appl. No.: 11/279,066

(22) Filed: Apr. 7, 2006

(51) Int. Cl. C23C 14/32; C23C 14/00

(52) U.S. Cl. 204/192.1; 204/298.02

(57) ABSTRACT

A method and system for performing multiple depositions on a substrate using an improved Ionized Physical Vapor Deposition (IPVD) system that allows IPVD processes and plasma-enhanced processes, such as PEALD and PECVD, to be performed in a single processing chamber. A determination of the state of an in-coming substrate can be made by sensing the substrate automatically or interrogating data relating to the state of the substrate to arrive at the determination. A controller selects and executes a process in response to the determination using a processing apparatus configured to alternatively perform multiple processes in response to commands from the controller.

### CROSS REFERENCE TO RELATED APPLICATIONS

This application is related to U.S. Ser. No. 11/090,255, Attorney Docket No. 267366US, Client Ref. No. TTCA 19, entitled “A PLASMA ENHANCED ATOMIC LAYER DEPOSITION SYSTEM”, now U.S. Pat. Appl. Publ. No. 200VVVVVVVVVVV, the entire contents of which are incorporated herein by reference. This application is related to U.S. Ser. No. 11/084,176, entitled “A DEPOSITION SYSTEM AND METHOD”, Attorney Docket No. 265595US, Client Ref. No. TTCA 24, now U.S. Pat. Appl. Publ. No. 200VVVVVVVVVVV, the entire contents of which are incorporated herein by reference. This application is related to U.S. Ser. No. 11/090,939, entitled “A PLASMA ENHANCED ATOMIC LAYER DEPOSITION SYSTEM HAVING REDUCED CONTAMINATION”, Client Ref. No. TTCA 27, now U.S. Pat. Appl. Publ. No. 200VVVVVVVVVVV, the entire contents of which are incorporated herein by reference. This application is related to U.S. Ser. No. 11/281,342, entitled “METHOD AND SYSTEM FOR PERFORMING PLASMA ENHANCED ATOMIC LAYER DEPOSITION”, Attorney Docket No. 274020US, Client Ref. No. TTCA 55, now U.S. Pat. Appl. Publ. No. 200VVVVVVVVVVV, the entire contents of which are incorporated herein by reference.

### BACKGROUND OF THE INVENTION

1. Field of the Invention

The present invention relates to an Ionized Physical Vapor Deposition (IPVD) system and a method of operating thereof, and more particularly to an IPVD system for performing multiple material deposition processes.

2. Description of Related Art

Typically, during materials processing, when fabricating composite material structures, plasma is employed to facilitate the addition and removal of material films. For example, in semiconductor processing, a dry plasma etch process is often utilized to remove or etch material along fine lines or within vias or contacts patterned on a silicon substrate. Alternatively, for example, a vapor deposition process is utilized to deposit material along fine lines or within vias or contacts on a silicon substrate. In the latter, vapor deposition processes include chemical vapor deposition (CVD), and plasma enhanced chemical vapor deposition (PECVD).

In PECVD, plasma is utilized to alter or enhance the film deposition mechanism. For instance, plasma excitation generally allows film-forming reactions to proceed at temperatures that are significantly lower than those typically required to produce a similar film by a thermal CVD process that thermally heats the process gas (without plasma excitation) to temperatures near or above the dissociation temperature of the process gas. In addition, plasma excitation may activate film-forming chemical reactions that are not energetically or kinetically favored in thermal CVD. The chemical and physical properties of PECVD films may thus be varied over a relatively wide range by adjusting process parameters.

More recently, atomic layer deposition (ALD) and plasma enhanced ALD (PEALD) have emerged as candidates for ultra-thin gate film formation in front end-of-line (FEOL) operations, as well as ultra-thin barrier layer and seed layer formation for metallization in back end-of-line (BEOL) operations. In ALD, two or more process gases, such as a film precursor and a reduction gas, are introduced alternatingly and sequentially while the substrate is heated in order to form a material film one monolayer at a time. In PEALD, plasma is formed during the introduction of the reduction gas to form a reduction plasma. To date, ALD and PEALD processes have proven to provide improved uniformity in layer thickness and conformality to features on which the layer is deposited, albeit these processes are slower than their CVD and PECVD counterparts.

### SUMMARY OF THE INVENTION

One object of the present invention is directed to addressing various problems with semiconductor processing at ever decreasing line sizes where conformality, adhesion, and purity are becoming increasingly important issues affecting the resultant semiconductor device.

Another object of the present invention is to reduce contamination problems between interfaces of subsequently deposited material layers.

Another object of the present invention is to provide an IPVD system capable of changing a process volume size in order to accommodate different deposition processes.

Another object of the present invention is to provide a configuration compatible for IPVD processes and plasma enhanced deposition processes within the same system.

Variations of these and/or other objects of the present invention are provided by certain embodiments of the present invention.

In one embodiment of the present invention, a method is provided for processing a substrate, including positioning the substrate on a substrate holder in a processing chamber of the IPVD system, the processing chamber having a first process space defined above the substrate; determining an in-coming state for the substrate; and either depositing an IPVD layer using an IPVD process when the in-coming state is equal to a first state or depositing a plasma-enhanced layer using a plasma-enhanced process when the in-coming state is equal to a second state.

The method can further include determining a processed state for the substrate; and either depositing an additional layer when the processed state is equal to a first state, or removing the substrate from the processing chamber when the processed state is equal to a second state.

In accordance with certain embodiments of the invention, sensing hardware and logic are provided to inspect the in-coming wafer, either at the processing module or upstream in the system, to make the determination of the state of the in-coming substrate, so that the module process controller can select the process to perform.

In accordance with other embodiments of the invention, the controller retrieves information from a database or other memory file that records the process history of the substrate, from which history the controller performs an analysis or otherwise processes information to determine the state of the substrate, so that, based on the determination, a process is selected and executed to process the wafer therewith.

Further in accordance with principles of the present invention, a semiconductor wafer processing module is configured to perform at least two alternative processes in response to a determination of the state of the in-coming substrate. The controller can then either respond to sensor outputs or stored information to determine the state of the in-coming wafer and to initiate a selected one of the alternative processes in response to the determination.

### BRIEF DESCRIPTION OF THE DRAWINGS

In the accompanying drawings, a more complete appreciation of the present invention and many attendant advantages thereof will be readily obtained as the same becomes better understood by reference to the following detailed description when considered in connection with the accompanying drawings, wherein:

FIG. 1 depicts a schematic view of an IPVD system in accordance with embodiments of the present invention;

FIG. 2 depicts another schematic view of an IPVD system in accordance with other embodiments of the invention;

FIG. 3 shows a process flow diagram of a method for operating an IPVD system in accordance with embodiments of the present invention; and

FIG. 4 depicts a schematic timing diagram in accordance with embodiments of the present invention.

### DETAILED DESCRIPTION OF PREFERRED EMBODIMENTS

In the following description, in order to facilitate a thorough understanding of the invention and for purposes of explanation and not limitation, specific details are set forth, such as a particular geometry of the IPVD system and descriptions of various components. However, it should be understood that the invention may be practiced in other embodiments that depart from these specific details.

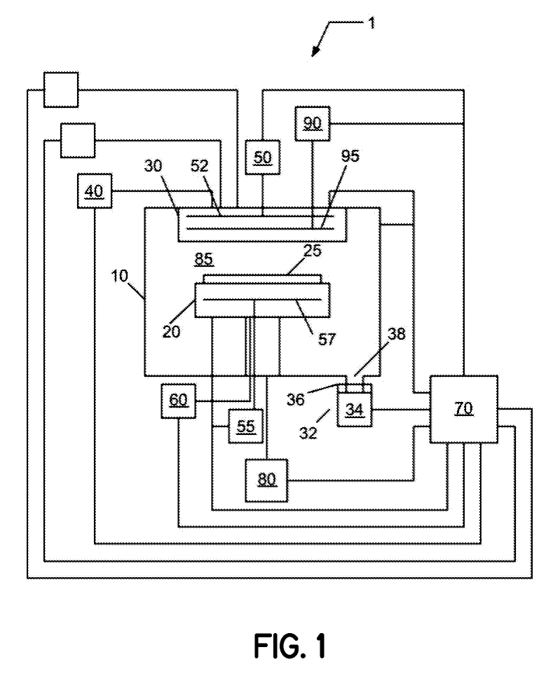

Referring now to the drawings, wherein like reference numerals designate identical or corresponding parts throughout the several views, FIG. 1 illustrates an IPVD system 1 for depositing a thin film, for example a barrier film, on a substrate using a deposition process, such as an ionized physical vapor deposition (IPVD) process, a plasma enhanced CVD (PECVD) process, an atomic layer deposition (ALD) process, or a plasma enhanced ALD (PEALD) process. During the metallization of inter-connect and intra-connect structures for semiconductor devices in back-end-of-line (BEOL) operations, a thin conformal barrier layer may be deposited on wiring trenches or vias to minimize the migration of metal into the inter-level or intra-level dielectric, a thin conformal seed layer may be deposited on wiring trenches or vias to provide a film with acceptable adhesion properties for bulk metal fill, and/or a thin conformal adhesion layer may be deposited on wiring trenches or vias to provide a film with acceptable adhesion properties for metal seed deposition. In addition to these processes, a bulk metal such as copper must be deposited within the wiring trench or via.

Oftentimes, for thin conformal films, i.e., barrier layers or seed layers, in back end metallization schemes, it is desirable to use a non-plasma deposition process, such as a thermal vapor deposition process, when depositing the initial thin conformal film over inter-level or intra-level dielectric. Particularly, when this dielectric layer comprises a low dielectric constant (low-k) material, exposure to plasma can cause damage to the low-k layer, that may, for example, affect an increase in the dielectric constant of the film. After using a thermal vapor deposition process to deposit the initial layer, an IPVD and/or plasma-enhanced deposition process may be utilized to improve deposition rate or film morphology or both.

These processes in the past typically could require separate chambers customized to the particular needs of each of these processes as no single chamber could accommodate all of the process requirements. For example, a thin film barrier layer is preferably performed at a self-limited ALD process to provide good conformality. Because ALD requires alternating different process gases, deposition occurs at a relatively slow deposition rate. The present inventors have recognized that performing a thermal ALD process in a small process space volume allows rapid gas injection and an evacuation of the alternating gases, which shortens the ALD cycle. On the other hand, metals, such as tantalum, titanium, tungsten, or copper can be deposited at a faster deposition rate by a thermal CVD process that does not necessarily require alternate gas flows. In this process it may be beneficial to use a larger process space volume to provide more uniform deposition of the material. As another example, described above, depositing one or more layers on a substrate may include a non-plasma process as well as a plasma process. The present inventors have recognized that the non-plasma process can benefit from a small process space volume to increase throughput and/or preserve process gas while a larger process space volume is required to sustain a uniform plasma.

The need for separate chambers adds costs due to the multiplicity of deposition units, adds time to the fabrication process due to the transfer between the systems of the processed substrate, and (due to the transfer between multiple deposition units) makes contamination of the exposed interfaces a concern which had to be addressed through preventive or remedial measures, thereby adding more costs and complexity to the fabrication process.

In FIG. 1, IPVD system 1 is illustrated for depositing a thin film, such as a barrier and/or seed layer, on a substrate using an IPVD process and/or a plasma-enhanced deposition process, such as a PECVD process, or a PEALD process according to embodiments of the present invention. IPVD system 1 can include a processing chamber 10 having a substrate holder 20 configured to support a substrate 25, upon which a thin film is to be formed. Additionally, the IPVD system 1 as illustrated in FIG. 1 includes a process volume adjustment system 80 coupled to the processing chamber 10 and the substrate holder 20, and configured to adjust the volume of the process space adjacent substrate 25. For example, the process volume adjustment system 80 can be configured to vertically translate the substrate holder 20 between one or more different positions thereby creating one or more different process space volumes.

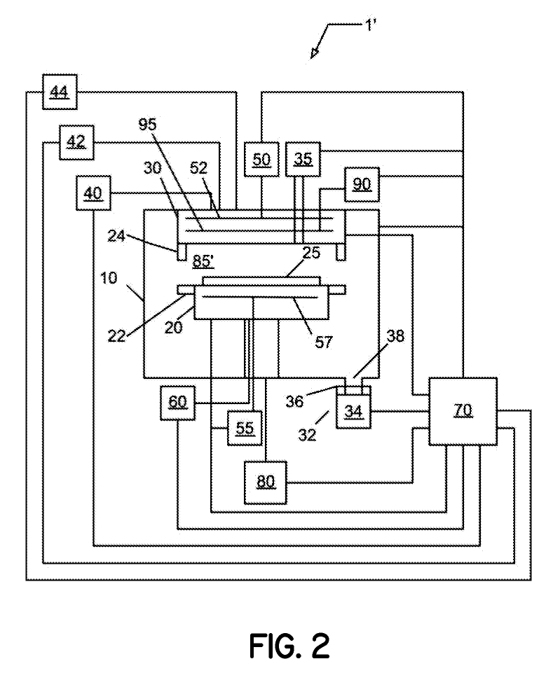

Referring now to FIG. 2, another IPVD system 1′ is illustrated for depositing a thin film, such as a barrier and/or seed layer, on a substrate using an IPVD process and/or a plasma-enhanced deposition process, such as a PECVD process, or a PEALD process according to additional embodiments of the present invention. The IPVD system 1′ includes many of the same features as IPVD system 1 illustrated in FIG. 1, which like reference numerals represent like components.

IPVD system 1′ can further include an upper shield 24 that can be configured to surround a peripheral edge of process space 85′ as shown in FIG. 2. Alternatively, the shield may be shaped and/or positioned differently. Substrate holder 20 can include a lower shield 22 configured to operate along with upper shield 24 to change the size of the process space 85′. The substrate holder 20 can be translated upwards and/or downwards to form and/or change the size of process space 85′. As mentioned above, the process volume adjustment system 80 can be configured to vertically translate the substrate holder 20 between one or more different positions thereby creating one or more different process space volumes. Alternatively, the lower shield 22 may not be required or may be shaped and/or positioned differently.

In one embodiment, lower shield 22 can be configured to seal with upper shield 24. In addition, lower shield 22 and/or upper shield 24 can be configured to permit passage of process gases there through (as in a perforated shield) in order to control the evacuation of and/or the flow through process space 85′.

In another embodiment, a separate vacuum pumping system 35 similar to vacuum pumping system 34 can be coupled to the processing chamber 10 and can be used to evacuate the process space 85′, when the upper shield 24 is sealed to the lower shield 22.

The lower shield 22 and/or upper shield 24 depicted in FIG. 2 can serve multiple purposes. The upper shield 24 can provide a simplified cylindrical geometry in which fluid flow in the process space 85′ can be more reliably predicted or controlled. The lower shield 22 and/or upper shield 24 can be used to control and/or change the size of process space 85′. For example, openings in the shields and/or between the shields can be used and/or controlled to control the fluid flow to improve plasma uniformity. Likewise, the lower shield 22 and/or upper shield 24 can provide a symmetrical path to electrical ground proximate the plasma edge, which can provide a uniform plasma that can be more reliably predicted or controlled. Furthermore, the lower shield 22 and/or upper shield 24 can be replaceable units, and can collect deposits that would normally accumulate on the interior surfaces of processing chamber 10. As such, lower shield 22 and/or upper shield 24 can be replaced in normal routine maintenance and extend the time period before the interior of walls 10 needs to be cleaned. Alternatively, the lower shield 22 and/or upper shield 24 can be cleaned in-situ to extend their maintenance cycle.

Referring now to FIGS. 1 and 2, IPVD systems (1, 1′) can include a substrate temperature control system 60 coupled to the substrate holder 20 and configured to elevate and control the temperature of substrate 25. Substrate temperature control system 60 can include temperature control elements, such as a cooling system including a re-circulating coolant flow that receives heat from substrate holder 20 and transfers heat to a heat exchanger system (not shown), or when heating, transfers heat from the heat exchanger system. Additionally, the temperature control elements can include heating/cooling elements, such as resistive heating elements, or thermoelectric heaters/coolers can be included in the substrate holder 20, as well as the chamber wall of the processing chamber 10 and any other component within the IPVD systems (1, 1′).

In order to improve the thermal transfer between substrate 25 and substrate holder 20, the substrate holder 20 can include a mechanical clamping system, or an electrical clamping system, such as an electrostatic clamping system, to affix substrate 25 to an upper surface of substrate holder 20. Furthermore, substrate holder 20 can further include a substrate backside gas delivery system configured to introduce gas to the backside of substrate 25 in order to improve the gas-gap thermal conductance between substrate 25 and substrate holder 20. Such a system can be utilized when temperature control of the substrate is required at elevated or reduced temperatures. For example, the substrate backside gas system can include a two-zone gas distribution system, wherein the backside gas gap pressure can be independently varied between the center and the edge of substrate 25.

The substrate holder 20 along with in vacuo mechanisms to translate the substrate holder and interior mechanisms for substrate temperature control system 60 can constitute a lower chamber assembly of the processing chamber 10.

The processing chamber 10 can further include an upper chamber assembly 30 coupled to a first precursor-containing gas composition supply system 40, a second precursor-containing gas composition supply system 42, and a process gas supply system 44. As such, the upper chamber assembly 30 can be configured to provide first precursor-containing gas composition and the second precursor-containing gas composition to process space (85, 85′). A showerhead design, as known in the art, can be used to uniformly distribute the first and second process gas materials into the process space (85, 85′). Exemplary showerheads are described in greater detail in pending U.S. Patent Application Pub. No. 20040123803, the entire contents of which is incorporated herein by reference in its entirety, and in previously incorporated by reference U.S. Ser. No. 11/090,255.

The IPVD systems (1, 1′) may be configured to process 200 mm substrates, 300 mm substrates, or larger-sized substrates. In fact, it is contemplated that the IPVD systems described in the present invention may be configured to process substrates, wafers, or LCDs regardless of their size, as would be appreciated by those skilled in the art. Substrates can be introduced to processing chamber 10, and the substrate may be lifted to and from an upper surface of substrate holder 20 via a substrate lift system (not shown).

According to one embodiment of the present invention, the first precursor-containing gas composition supply system 40 and the second precursor-containing gas composition gas supply system 42 can be configured to sequentially and optionally alternatingly introduce a first precursor-containing gas composition to processing chamber 10 and a second precursor-containing gas composition to processing chamber 10 in order to sequentially and optionally alternatingly deposit first and second films on substrate 25. The alternation of the introduction of the first precursor-containing gas composition and the introduction of the second precursor-containing gas composition can be cyclical, or it may be acyclical with variable time periods between introduction of the first and second process gas materials. The first and second process gas materials can, for example, include a gaseous film precursor, such as a composition having the principal atomic or molecular species found in the films formed on substrate 25. The gaseous film precursor can originate as a solid phase, a liquid phase, or a gaseous phase, and may be delivered to processing chamber 10 in a gaseous phase. The first and second process gas materials can, for example, include a reduction gas. For instance, the reduction gas can originate as a solid phase, a liquid phase, or a gaseous phase, and may be delivered to processing chamber 10 in a gaseous phase. Examples of gaseous film precursors and reduction gases are given below.

When introducing the first precursor-containing gas composition or the second precursor-containing gas composition to form the first film or the second film, respectively, the gaseous components, i.e., film precursor and reduction gas, of the first precursor-containing gas composition or the second precursor-containing gas composition may be introduced together at the same time to processing chamber 10. For example, the film precursor and the reduction gas may be mixed or they may be un-mixed prior to introduction to processing chamber 10. Alternatively, the gaseous components of the first precursor-containing gas composition or the second precursor-containing gas composition may be sequentially and alternatingly introduced to processing chamber 10. Plasma may or may not be utilized to assist the deposition of the first film and the second film on substrate 25 using the first precursor-containing gas composition and the second process gas material, respectively.

The first precursor-containing gas composition supply system 40, the second precursor-containing gas composition supply system 42, and the process gas supply system 44 can include one or more precursor sources, one or more gas sources, one or more pressure control devices, one or more flow control devices, one or more filters, one or more valves, or one or more flow sensors. The process gas supply system 44 can be used to provide a purge gas during a plasma-enhanced process and can be used to provide one or more process gasses during an IPVD process. The flow control devices can include pneumatic driven valves, electro-mechanical (solenoidal) valves, and/or high-rate pulsed gas injection valves. An exemplary pulsed gas injection system is described in greater detail in pending U.S. Patent Application Pub. No. 20040123803, the entire contents of which are incorporated herein by reference. Precursor-containing, purge, and/or process gasses can be pulsed during plasma-enhanced processes and/or IPVD processes to improve the film quality.

In addition, the IPVD systems (1, 1′) can comprise a target 90 that is coupled to a target supply source 90. DC power can be supplied from a power source 95 to the target 90. The controller 70 can be used to determine the amount of DC power to provide and when to have it applied to the target, and the DC power can range from approximately 100 watts to approximately 3000 watts during a barrier deposition process. For example, an upper limit for the DC power level can be established to prevent target poisoning.

The IPVD systems (1, 1′) can be used to perform a number of IPVD (sputter deposition) processes and the IPVD systems (1, 1′) can be configured for a number of different targets that can include tantalum (Ta), titanium, (Ti), ruthenium (Ru), iridium (Ir), aluminum (Al), silver (Ag), lead (Pt), or copper (Cu), or a combination thereof.

The IPVD systems (1, 1′) can comprise a magnet assembly (not shown) that can be used to produce and/or change a magnetic field shape in a process volume within the chamber. Alternatively, a magnet assembly may not be required. In addition, certain embodiments can be configured to have either a reduced strength static magnetic field in vicinity of the target surface or with no static cathode magnetic field. A weak magnet configuration may be used to maintain the static magnetic field shape and orientation so that the field within the target area and the nearby plasma generates an optimal erosion profile for high target utilization. Such low or reduced field strength can be maintained constant in the IPVD processes, or may be changed to a different level during the IPVD process. For example, a controllable magnetic field may be used to provide a weak or zero static magnetic field, for example less than 10 Gauss, in the process space (86, 85′). Furthermore, a controllable magnetic field may be used to reduce and/or reshape the magnetic field to adjust the field uniformity across the target surface.

The IPVD systems (1, 1′) can be used to perform a number of different IPVD (sputter deposition) processes. In some examples, No Net Deposition (NND) processes can be performed in which there is substantially no net deposition in the field area of the substrate and a there is a controlled amount of deposition on feature sidewalls, feature corners, and the bottom of the feature. In other examples, Low Net Deposition (LND) processes can be performed in which there is controlled amount of deposition in the field area of the substrate, and there is a controlled amount of deposition on feature sidewalls, feature corners, and the bottom of the feature. The controlled amounts can be percentages of the amount deposited in the field area. In additional examples, dry-filling processes can be performed to uniformly fill features with a metal such as copper, thereby eliminating the plating process. In still other examples, a shaping plasma can be used to minimize and/or eliminate the material at the feature openings.

In addition, the IPVD systems (1, 1′) can be used to perform improved LND processes to deposit ultra-thin (<4 nm) layers, and the improved LND process can include a lower deposition rate and a higher ionization that allows a more etch resistant barrier to be deposited. An ultra-thin barrier can be deposited and the ultra-thin barrier can still act as barrier to Cu diffusion as well as “etch stop” layer for subsequent deposition/etch processes, such as Ta (for wetting) layer or Cu for seed layer. For example, a process can be provided that involves depositing a thin layer of metallization, for example, tantalum (Ta), tantalum nitride (TaN), Ruthenium (Ru), and/or copper (Cu) into features of the substrate.

In the metallization of ultra-small (<30 nm) high aspect ratio (>3) via holes and trenches on semiconductor substrates, it is required that the barrier layer and the seed layer have good sidewall and bottom coverage. The barrier layer needs to be as thin as possible without sacrificing its barrier properties. The barrier layer must be thin because its electrical resistance, which adds to the electrical resistance of the via structure, must be minimized. It needs to be conformal and continuous to prevent diffusion of seed layer material into the dielectric layer and into other layers to prevent reliability problems. This requires that the barrier layer thickness must be well controlled and minimized especially at the bottom of the via. A thick barrier layer at the bottom of the via may add substantial undesirable electrical resistance to the resistance of interconnect metallization.

In the LND barrier deposition process, metal can be sputtered off the target at a low rate. This results in only a minor dilution of the process gas ion plasma. The metal ionizes and is deposited on the substrate with a rate that can be less than 10 nm/min. A low bias is applied to the substrate to attract the ions to the bottom of the feature. Because of the low field deposition rate and the low bias, the metal deposits with little or no overhang developing. The sidewall coverage is enhanced, and the result is a highly conformal metal deposition, ideal for a barrier metal.

In some cases a reactive gas can be added during the LND barrier deposition process. During the barrier deposition process, the reactive gas flow rate is controlled so that the LND/IPVD process is performed in a target non-poisoned mode or metal mode. For example, a nitrogen flow rate can be varied to grade the metal nitride composition from a nitrogen rich to nitrogen deficient metal nitride or from a nitrogen deficient to nitrogen rich metal nitride with this invention. This feature is highly desirable because it allows the user to tailor the stoichiometry of the metal nitride. Whether better barrier properties (higher N₂ content) are desired, or better wetting properties (lower N₂ content) are necessary, this invention can accommodate the user's needs. For example, the sidewall stoichiometry of a metal nitride can be controlled throughout the deposition process by varying nitrogen or reactive gas flow. In addition, the nitridization of a metal film sidewall can be controlled by controlling an Ar/N₂ ratio during the barrier deposition process.

Referring still to FIGS. 1 and 2, the IPVD systems (1, 1′) can include a plasma generation system configured to generate plasma during at least a portion of an IPVD process and/or during at least a portion of a plasma-enhanced deposition process. In various embodiments, plasma can be generated before, during, and/or after a precursor containing gas is introduced to the process space (85, 85′). In other embodiments, plasma can be generated before, during, and/or after a process gas and/or a purge gas is introduced to the process space (85, 85′).

The plasma generation system can include a first power source 50 coupled to an antenna 52 that is coupled to the processing chamber 10. Antenna 52 can be configured to couple power to the process space (85, 85′) during at least a portion of an IPVD process and/or during at least a portion of a plasma-enhanced deposition process. The first power source 50 may include a radio frequency (RF) generator and an impedance match network (not shown). The antenna 52 can be formed in the upper assembly 30, or outside the upper assembly 30, and it can be configured to oppose the substrate holder 20. Alternatively, power may be coupled to the processing space (85, 85′) using one or more coils that surround a portion of the processing chamber 10.

Those skilled in the art will recognize that the impedance match network not shown) can be configured to optimize the transfer of RF power from the RF generator to the plasma by matching the output impedance of the match network with the input impedance of the processing chamber, including the electrode, and plasma. For instance, the impedance match network serves to improve the transfer of RF power to plasma in plasma processing chamber 10 by reducing the reflected power. Match network topologies (e.g. L-type, □-type, T-type, etc.) and automatic control methods are well known to those skilled in the art. A typical frequency for the RF power can range from about 0.1 MHz to about 100 MHz. Alternatively, the RF frequency can, for example, range from approximately 400 kHz to approximately 60 MHz, By way of further example, the RF frequency can, for example, be approximately 13.56 or 27.12 MHz.

The IPVD systems (1, 1′) can include a substrate bias generation system configured to provide a bias to the substrate during at least a portion of the plasma-enhanced process and/or during at least a portion of the IPVD process. The substrate bias system can include a second power source 55 coupled to an electrode 57 in the substrate holder 20 in the processing chamber 10, and configured to couple power to substrate holder 20, and thereby provide a bias to the substrate 25. The second power source 55 may include a radio frequency (RF) generator and an impedance match network (not shown) that may be coupled to electrode 57, and through which RF power is coupled to substrate 25. The electrode can be formed in substrate holder 20. Alternatively, substrate holder 20 can be electrically biased with a DC voltage. A typical frequency for the RF bias can range from about 0.1 MHz to about 100 MHz. Alternately, RF power can be applied to the substrate holder electrode 57 at multiple frequencies. Alternatively, the RF frequency can, for example, range from approximately 400 kHz to approximately 60 MHz. By way of further example, the RF frequency can, for example, be approximately 13.56 or 27.12 MHz. The substrate bias generation system may operate at a different or the same frequency as the plasma generation system.

Although the first power source 50 and the second power source 55 are illustrated in FIG. 1 as separate entities, these power sources may be part of a single power system.

Furthermore, the processing chamber 10 can be coupled to a pressure control system 32, which can include for example a vacuum pumping system 34, a valve 36, and a duct 38. The pressure control system 34 can be configured to controllably evacuate the processing chamber 10 to a pressure suitable for performing an IPVD process to deposit one or more thin films on substrate 25, and suitable for performing a plasma-enhanced process to deposit one or more thin films on substrate 25 use of the first and second precursor-containing gas compositions.

The vacuum pumping system 34 can include a turbo-molecular vacuum pump (TMP) capable of a pumping speed up to about 5000 liters per second (and greater) and valve 36 can include a gate valve for throttling the chamber pressure. For example, a 1000 to 3000 liter per second TMP may be employed. In addition, one or more devices for monitoring chamber pressure (not shown) can be coupled to the processing chamber 110. Furthermore, one or more devices for monitoring exhaust flow and/or chemistry (not shown) may be included in the pressure control system 32.

Still referring to FIGS. 1 and 2, IPVD systems (1, 1′) can include a controller 70 that can be coupled to processing chamber 10, substrate holder 20, upper assembly 30, pressure control system 32, first precursor-containing gas composition supply system 40, second precursor-containing gas composition supply system 42, process gas supply system 44, first power source 50, second power source 55, substrate temperature control system 60, process volume adjustment system 80, and target supply source 90. Alternatively, controller 70 may be coupled differently. For example, one or more magnet assemblies (not shown) may be coupled to the controller.

The controller 70 can include a microprocessor, memory, and a digital I/O port capable of generating control voltages sufficient to communicate and activate inputs to IPVD systems (1, 1′) as well as monitor outputs from IPVD systems (1, 1′) in order to control and monitor the an IPVD process and/or plasma-enhanced process for film deposition. For example, the controller 70 can include computer readable medium containing program instructions for execution to accomplish the procedures described herein. Moreover, the controller 70 may be coupled to and may exchange information with the process chamber 10, substrate holder 20, upper assembly 30, pressure control system 32, first precursor-containing gas composition gas supply system 40, second precursor-containing gas composition supply gas system 42, process gas supply system 44, first power source 50, second power source 55, substrate temperature controller 60, process volume adjustment system 80, and target supply source 90. For example, a program stored in the memory may be utilized to activate the inputs to the aforementioned components of the IPVD systems (1, 1′) according to a process recipe in order to perform one of the above-described IPVD or plasma enhanced deposition processes.

The controller 70 can be implemented as a general-purpose computer system that performs a portion or all of the microprocessor based processing steps of the invention in response to a processor executing one or more sequences of one or more instructions contained in a memory. Alternatively, the controller 70 may be implemented using microprocessors in one or more of IPVD subsystems, and one or more of these microprocessors may perform a portion of the processing steps described herein. Instructions, data, and/or commands may be read into and/or out of the controller memory from and/or to another computer readable medium, such as a hard disk or a removable media drive. One or more processors in a multiprocessing arrangement may also be employed as the controller microprocessor to execute the sequences of instructions contained in main memory. In alternative embodiments, firmware data may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention.

Stored on any one or on a combination of computer readable media, the present invention includes software for controlling the controller 70, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the IPVD systems (1, 1′), or it may be remotely located relative to the IPVD systems (1, 1′). For example, the controller 70 may exchange data with the IPVD systems (1, 1′) using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the IPVD systems (1, 1′) via a wireless connection.

In some examples, a plasma-enhanced deposition process, such as a PEALD or PECVD process, can be performed using the IPVD systems (1, 1′) described in FIGS. 1 and 2, and plasma-enhanced process recipes can be established for depositing tantalum (Ta), tantalum nitride, or tantalum carbonitride films. The plasma-enhanced recipe can include performing a first precursor-containing gas composition step that is followed by a first purge gas step, and then performing a second precursor-containing gas composition step that is followed by a second purge gas step. For example, the first precursor-containing gas composition step may include a Ta carrier such as TaF₅, TaCl₅, TaBr₅, TaI₅, Ta(CO)₅, Ta[N(C₂H₅CH₃)]₅ (PEMAT), Ta[N(CH₃)₂]₅ (PDMAT), Ta[N(C₂H₅)₂]₅ (PDEAT), Ta(NC(CH₃)₃)(N(C₂H₅)₂)₃ (TBTDET), Ta(NC₂H₅)(N(C₂H₅)₂)₃, Ta(NC(CH₃)₂C₂H₅)(N(CH₃)₂)₃, or Ta(NC(CH₃)₃)(N(CH₃)₂)₃, that absorbs on the surface of the substrate, and the second precursor-containing gas composition step can include the introduction of a reduction gas such as H₂, NH₃, N₂ and H₂, N₂H₄, NH(CH₃)₂, or N₂H₃CH₃. Alternatively, other process recipe sequences may be used.

Alternatively, a thermally-driven vapor deposition process, such as an ALD or CVD process, can be performed using the IPVD systems (1, 1′) described in FIGS. 1 and 2 to deposit tantalum (Ta), tantalum nitride, or tantalum carbonitride films.

In other examples, a plasma-enhanced deposition process, such as a PEALD or PECVD process, can be performed using the IPVD systems (1, 1′) described in FIGS. 1 and 2, and plasma-enhanced recipes can be established for depositing titanium (Ti), titanium nitride, or titanium carbonitride films. The plasma-enhanced process recipe can include performing a first precursor-containing gas composition step that is followed by a first purge gas step, and then performing a second precursor-containing gas composition step that is followed by a second purge gas step. For example, the first precursor-containing gas composition step may include a the Ti carrier can include TiF₄, TiCl₄, TiBr₄, TiI₄, Ti[N(C₂H₅CH₃)]₄ (TEMAT), Ti[N(CH₃) 2]4 (TDMAT), or Ti[N(C₂H₅)₂]₄ (TDEAT), that absorbs on the surface of the substrate, and the second precursor-containing gas composition step can include the introduction of a reduction gas such as H₂, NH₃, N₂ and H₂, N₂H₄, NH(CH₃) 2, or N₂H₃CH₃, or a combination thereof. Alternatively, other process recipe sequences may be used.

Alternatively, a thermally-driven vapor deposition process, such as an ALD or CVD process, can be performed using the IPVD systems (1, 1′) described in FIGS. 1 and 2 to deposit titanium (Ti), titanium nitride, or titanium carbonitride films.

In additional examples, a plasma-enhanced deposition process, such as a PEALD or PECVD process, can be performed using the IPVD systems (1, 1′) described in FIGS. 1 and 2, and plasma-enhanced process recipes can be established for depositing tungsten (W), tungsten nitride, or tungsten carbonitride films. The plasma-enhanced process recipe can include performing a first precursor-containing gas composition step that is followed by a first purge gas step, and then performing a second precursor-containing gas composition step that is followed by a second purge gas step. For example, the first precursor-containing gas composition step may include a the W carrier can include WF₆, or W(CO)₆ that absorbs on the surface of the substrate, and the second precursor-containing gas composition step can include the introduction of a reduction gas such as H₂, NH₃, N₂ and H₂, N₂H₄, NH(CH₃)₂, or N₂H₃CH₃, or a combination thereof. Alternatively, other process recipe sequences may be used.

Alternatively, a thermally-driven vapor deposition process, such as an ALD or CVD process, can be performed using the IPVD systems (1, 1′) described in FIGS. 1 and 2 to deposit tungsten (W), tungsten nitride, or tungsten carbonitride films.

In other additional examples, a plasma-enhanced deposition process, such as a PEALD or PECVD process, can be performed using the IPVD systems (1, 1′) described in FIGS. 1 and 2, and plasma-enhanced process recipes can be established for depositing copper films. The plasma-enhanced process recipe can include performing a first precursor-containing gas composition step that is followed by a first purge gas step, and then performing a second precursor-containing gas composition step that is followed by a second purge gas step. For example, the first precursor-containing gas composition step may include a the Cu carrier can include Cu-containing organometallic compounds, such as Cu(TMVS)(hfac), also known by the trade name CupraSelect®, available from Schumacher, a unit of Air Products and Chemicals, Inc., 1969 Palomar Oaks Way, Carlsbad, Calif. 92009), or inorganic compounds, such as CuCl that absorbs on the surface of the substrate, and the second precursor-containing gas composition step can include the introduction of a reduction gas such as H₂, O₂, N₂, NH₃, or H₂O or a combination thereof. Alternatively, other process recipe sequences may be used.

Alternatively, a thermally-driven vapor deposition process, such as an ALD or CVD process, can be performed using the IPVD systems (1, 1′) described in FIGS. 1 and 2 to deposit copper films.

In more additional examples, a plasma-enhanced deposition process, such as a PEALD or PECVD process, can be performed using the IPVD systems (1, 1′) described in FIGS. 1 and 2, and plasma-enhanced process recipes can be established for depositing Ruthenium (Ru) films. The plasma-enhanced process recipe can include performing a first precursor-containing gas composition step that is followed by a first purge gas step, and then performing a second precursor-containing gas composition step that is followed by a second purge gas step. For example, the first precursor-containing gas composition step may include a ruthenium carbonyl precursor such as Ru3(CO)12, or a ruthenium organometallic precursor such as (2,4-dimethylpentadienyl)(ethylcyclopentadienyl) ruthenium (Ru(DMPD)(EtCp)), bis(2,4-dimethylpentadienyl) ruthenium (Ru(DMPD)2), or (2,4-dimethylpentadienyl) (methylcyclopentadienyl) ruthenium W(CO)₆ that absorbs on the surface of the substrate, and the second precursor-containing gas composition step can include the introduction of a reduction gas such as H₂, NH₃, N₂ and H₂, N₂H₄, NH(CH₃)₂, or N₂H₃CH₃, or a combination thereof. Alternatively, other process recipe sequences may be used.

Alternatively, a thermally-driven vapor deposition process, such as an ALD or CVD process, can be performed using the IPVD systems (1, 1′) described in FIGS. 1 and 2 to deposit ruthenium films.

In further examples, a plasma-enhanced deposition process, such as a PEALD or PECVD process, can be performed using the IPVD systems (1, 1′) described in FIGS. 1 and 2, and plasma-enhanced process recipes can be established for depositing tungsten (W), tungsten nitride, or tungsten carbonitride films. The plasma-enhanced process recipe can include performing a first precursor-containing gas composition step that is followed by a first purge gas step, and then performing a second precursor-containing gas composition step that is followed by a second purge gas step. For example, the first precursor-containing gas composition step may include a the W carrier can include WF₆, or W(CO)₆ that absorbs on the surface of the substrate, and the second precursor-containing gas composition step can include the introduction of a reduction gas such as H₂, NH₃, N₂ and H₂, N₂H₄, NH(CH₃)₂, or N₂H₃CH₃, or a combination thereof. Alternatively, other process recipe sequences may be used.

Alternatively, a thermally-driven vapor deposition process, such as an ALD or CVD process, can be performed using the IPVD systems (1, 1′) described in FIGS. 1 and 2 to deposit tungsten (W), tungsten nitride, or tungsten carbonitride films.

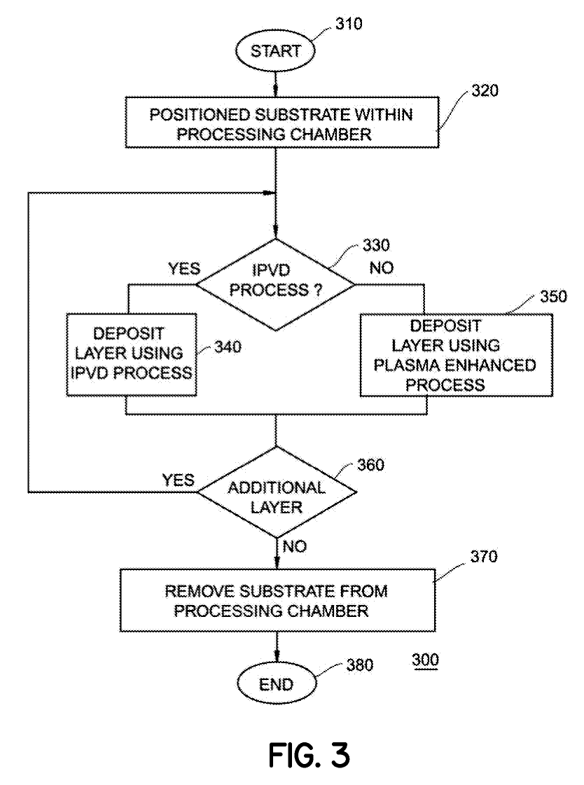

FIG. 3 illustrates a method for using an IPVD system for depositing multiple films in accordance with embodiments of the invention. Procedure 300 starts in 310.

In 320, a patterned substrate/wafer can be positioned on a substrate holder in a processing chamber in an IPVD system as described herein. Alternately, a non-patterned substrate/wafer may be used.

In 330, a query can be performed to determine if an IPVD (sputter deposition) process is required. When an IPVD (sputter deposition) process is required, procedure 300 can branch to 340 and procedure 300 can continue as shown in FIG. 3. When an IPVD (sputter deposition) process is not required, procedure 300 can branch to 350 and procedure 300 can continue as shown in FIG. 3.

The in-coming state of the substrate can be determined when a single substrate is received or when a group (lot/batch) of substrates is received. Alternatively, the in-coming state of the substrate may be determined before or after a single substrate is received, or before of after a group (lot/batch) of substrates is received. When the in-coming state is equal to a first state, an IPVD process can be performed on the substrate, and when the in-coming state is equal to a second state, a plasma-enhanced process can be performed on the substrate.

In 340, a film can be deposited on the substrate using an IPVD process. The IPVD systems (1, 1′) can be configured to deposit one or more layers using a sputter deposition process. For example, Low Net Deposition (LND) and/or No Net Deposition (NND) processes can be performed.

Examples of iPVD systems are described in U.S. Pat. Nos. 6,287,435; 6,080,287; 6,197,165 and 6,132,564, and these patents are hereby expressly incorporated herein by reference. Examples of IPVD systems having reduced and controllable magnetic fields are described in U.S. Pat. App. 20040188239, and this patent application is incorporated herein by reference.

Deposition techniques for IPVD systems are taught in (TTCA-129), (TTCA-130), co-pending U.S. patent application Ser. No. 11/091,741, entitled “Improved Ionized Physical Vapor Deposition (iPVD) Process” by Cerio, filed on Mar. 28, 2005, and co-pending U.S. patent application Ser. No. 10/811,326, entitled “Ionized Physical Vapor Deposition (iPVD) Process” by Cerio, et al, filed on Mar. 26, 2004, and all are incorporated by reference herein.

Alternatively, the IPVD systems (1, 1′) may be configured to fill a feature using a dry-fill process. Dry-filling techniques are taught in co-pending U.S. patent application Ser. No. 11/241,741, entitled “A Method and Apparatus for Metallic Dry-Filling Process” by Cerio, filed on Sep. 30, 2005, and co-pending U.S. patent application Ser. No. 11/241,742, entitled “A Method and Apparatus for a Metallic Dry-Filling Process” by Cerio, filed on Sep. 30, 2005, and these two patent applications are incorporated by reference herein.

Improved temperature control techniques are taught in co-pending U.S. patent application (TTCA-129), entitled “Temperature-Controlled Metallic Dry-Filling Process” by Cerio, filed herewith and incorporated by reference herein.

Techniques for improved barriers are taught in co-pending U.S. patent application (TTCA-130), entitled “Barrier Deposition Using Ionized Physical Vapor Deposition (IPVD)” by Cerio, filed herewith and incorporated by reference herein.

The IPVD systems (1, 1′) can comprise a gas supply system 40 that is coupled to the processing chamber, and the gas supply system 40 can be used to flow process gas into the processing chamber during one or more parts of the IPVD process. The process gas can comprise an inert gas, or a nitrogen-containing gas, or an oxygen-containing gas, or a silicon-containing gas, or a combination thereof. The nitrogen-containing gas can comprise N₂, NO, N₂O, and NH₃, the oxygen-containing gas can comprise O₂, NO, N₂O, or H₂O, and the inert gas can comprise argon, helium, krypton, radon, xenon, or a combination thereof. In some IPVD process, the processing gas can be pulsed.

During an IPVD process, the process gas flow rate can range from approximately 0 sccm to approximately 1000 sccm. When an inert gas is used during an IPVD process, the flow rates for the inert gas can range from approximately 0 sccm to approximately 1000 sccm. When a nitrogen-containing gas is used during an IPVD process, the flow rate for the nitrogen-containing gas can range from approximately 0 sccm to approximately 1000 sccm. When an oxygen-containing gas is used during an IPVD process, the flow rate for the oxygen-containing gas can range from approximately 0 sccm to approximately 1000 sccm. When a silicon-containing is used during an IPVD process, the flow rates for the silicon-containing gas can range from approximately 0 sccm to approximately 1000 sccm.

During an IPVD process, a metallic target can be used to provide a source of metal ions. A DC power source can be coupled to the metallic target. In various embodiments, the DC power can range from approximately 0 watts to approximately 3000 watts during a barrier deposition process. For example, an upper limit for the DC power level can be established to prevent target poisoning.

During an IPVD process, one or more metallic layers can be deposited, and the metallic layers can include Ta-containing layers, Ti-containing layers, W-containing layers, Ru-containing layers, Ir-containing layers, Al-containing layers, Ag-containing layers), Pt-containing layers, or Cu-containing layers, or a combination thereof. For example, metal ions can diffuse towards the substrate surface based on the substrate bias power, and can be affected by a self-bias voltage within a plasma sheath, which is the potential difference between the potential of the plasma and the potential at the substrate surface.

In addition, during IPVD processes nitridation ratios, or oxidation ratios, or silicidation ratios, or metal ratios, or other ratios can be controlled to optimize film properties. For example, a TaN barrier can be deposited with higher N concentration (higher N/Ta ratio) thereby providing a harder and more etch resistant TaN barrier. An ultra-thin barrier can be deposited and the ultra-thin barrier can still act as barrier to Cu diffusion as well as “etch stop” layer for subsequent deposition/etch processes, such as Ta (for wetting) layer or Cu for seed layer, or a Ru barrier layer. Furthermore, the present invention provides a stable metal mode with a high N/Ta ratio, and does not allow the target to become poisoned (nitrated).

In one embodiment, an IPVD process can be performed in the simultaneous control of the target power and the RF substrate bias power is used a provide a process that deposits a ultra-thin layer of metal into the features of the substrate and causes a small amount of material to be deposited in the field area of the substrate. For example, a process can be provided that involves depositing a thin layer of metal, for example, Ta, Ru, TaN, or Cu into features of the substrate.

When an IPVD process is required, a patterned substrate/substrate can be positioned on a substrate holder 20 and held using an electrostatic chuck (not shown). Alternatively, an electrostatic chuck may not be required. The process volume adjustment system 80 can be used to vertically translate the substrate holder 20 to establish the required gap between the target and the substrate. Alternatively, the gap can be established at a different time or the gap can be changed. For example, the gap may be changed when plasma is not present. The gap size can range from approximately 100 mm to 400 mm. Alternatively, the gap can range from approximately 200 mm to 300 mm.

Before, during, and/or after an IPVD process is performed, the substrate temperature control system 60 can be used to control the temperature of the substrate holder 20 and the temperature of the substrate 25. In various embodiments, the substrate holder temperature may vary from approximately −50 degrees Celsius to approximately 300 degrees Celsius. In addition, a backside gas may be used to control a thermal conductivity value between the substrate holder 20 and the substrate 25.

During one or more portions of an IPVD process, a high-density plasma can be created using one or more process gasses that can be flowed into the processing chamber using the process gas supply system 44. In addition, the plasma can be extinguished and/or cycled during an IPVD process. Alternatively, a shaping plasma may be used during an IPVD process to shape feature openings. The process gasses can comprise an inert gas, a nitrogen-containing gas, an oxygen-containing gas, a metal-containing gas, or a combination thereof. In various embodiments, RF power can be provided to antenna 52 from the first power source 50. The first power source 50 can be a RF generator that can operate in a frequency range from approximately 1.0 MHz to approximately 100 MHz and can provide a power output that range from approximately 1000 watts to approximately 10000 watts.

In addition, a RF bias power level can be provided by the second power source 55 that can be a RF source that can operate in a frequency range from approximately 1.0 MHz to approximately 100 MHz and can provide a power output that range from approximately 0 watts to approximately 6000 watts.

Furthermore, power can be provided to the target 95 using the target supply source 90, and target supply source 90 can provide a DC power that can range from approximately 0 watts to approximately 6000 watts. The target power can be cycled during the IPVD process.

Furthermore, during the IPVD process, a chamber pressure, a chamber temperature, a substrate temperature, a process gas chemistry, a process gas flow rate, a gap size, an ICP power, substrate position, a target power, or a RF substrate bias power, or a combination thereof can be adjusted to establish and/or maintain the required deposition rate. As the IPVD process is performed material can be deposited into features of the patterned substrate while producing substantially no overhanging material at openings of the features and a low net deposition in the field area of the substrate. In addition, a number of deposition cycles can be perform, and when multiple cycles are performed the process parameters can remain constant, or alternatively one or process parameters can change during different cycles.

The IPVD deposition rate can comprise a field deposition rate that can range from approximately −10 nm/min to approximately +10 nm/min; a sidewall deposition rate that can range from approximately −1 nm/min to approximately +10 nm/min; and bottom surface deposition rate can range from approximately −10 nm/min to approximately +10 nm/min. For example, sidewall deposition rate can vary from approximately 20% to approximately 100% of the field deposition rate, and the bottom surface deposition rate can range from approximately 20% to approximately 100% of the field deposition rate.

In the IPVD process, a deposition time period may be used to add material on the field area on the top surface of the substrate and a shaping (DC-off) time may be used to remove an amount of material on the field area on the top surface of the substrate, and thus there is a low net deposition at the end of the process cycle on the field area on the top surface of the substrate. In addition, during the NND process, the deposition component may add material on the bottom and/or side surfaces of features on the substrate and the etching (sputtering) component may remove a lesser amount of material on the bottom and/or side surfaces of features on the substrate, and thus there is a net deposition at the end of the process cycle on the bottom and/or side surfaces of features on the substrate. The deposition/etch cycle can be repeated as many times as needed to achieve the desired result. By adjusting the DC level and the RF substrate bias levels, the overhang growth is eliminated or minimized. The overhang may be etched back and redistributed at least partially to the sidewalls. For example, a sputtering component may be used to remove some of the excess material from the via bottom and from the overhangs. When the metal layer is copper, the etch process increases the continuity of the Cu on the bottom and top portions of the feature sidewalls by redeposition of Cu sputtered from the via bottom and from the overhang at the via entrance. If the metal being etched is a barrier layer, the decrease in the thickness at the via bottom reduces the overall contact resistance of the via and improves device performance.

In 350, a film can be deposited on the substrate using a plasma enhanced process that can include a PEALD process or a PECVD process, or a combination thereof. The IPVD systems (1, 1′) can be configured to deposit one or more ultra-thin layers using a plasma enhanced deposition process, such as a PEALD or a PECVD deposition process. Alternatively, the IPVD systems (1, 1′) may be configured to deposit one or more ultra-thin layers using a thermally activated vapor deposition process, such as an ALD or a CVD deposition process.

In some embodiments, the substrate holder can be vertically translated, and a first process space (85, 85′) can be to established in the processing chamber above the substrate. During some processes, the size of the process space (85, 85′) can be dynamically changed during the process, and in other processes, the size of the process space (85, 85′) can remain fixed during the process.

A first plasma enhanced process recipe can be used to control the IPVD systems (1, 1′) shown in FIGS. 1 and 2. A first precursor-containing gas composition can be introduced into the first process space (85, 85′), and a first precursor material can be deposited on the substrate. For example, the first precursor-containing gas composition can be introduced using a shower plate assembly and/or an injection ring assembly.

In some embodiments, the volume of the process space (85, 85′) can be changed from a first volume to a second volume. Alternatively, the process space volume may be maintained.

Next, a second precursor-containing gas composition can be introduced into the process space (85, 85′), and a second precursor material can be deposited on top of the first precursor material. For example, the second precursor-containing gas composition can be introduced using a shower plate assembly and/or an injection ring assembly.

A plasma can be generated during the introduction of the second precursor-containing gas composition, thereby accelerating a reduction reaction between the first precursor material and second precursor material at a surface of the substrate. The plasma can be generated by providing RF power to the antenna 52 that is coupled to the process space (85, 85′).

The first film can be formed on the substrate by alternatingly introducing the first precursor-containing gas composition and second precursor-containing gas composition one or more times.

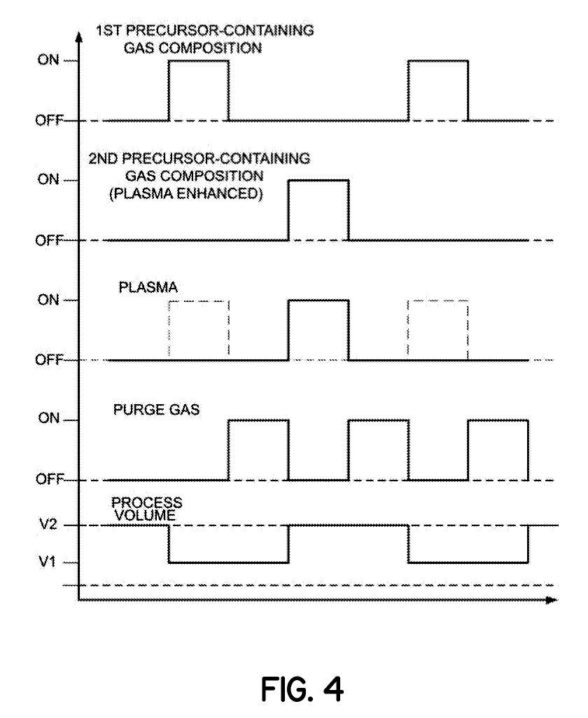

FIG. 4 depicts a schematic timing diagram in accordance with embodiments of the present invention. In the illustrated embodiment, a multi-step deposition process is shown in which one or more precursor-containing gasses can be used. The IPVD systems (1, 1′) can be configured to deposit multiple ultra-thin layers using a plasma enhanced deposition process, such as a PEALD or a PECVD deposition process. Alternatively, the IPVD systems (1, 1′) or 1′ may be configured to deposit multiple ultra-thin layers using a thermally activated vapor deposition process, such as an ALD or a CVD deposition process.

In some embodiments, the plasma enhanced deposition process can be preceded by an IPVD sputter deposition process, and in other embodiments, the plasma enhanced deposition process can be followed by an IPVD sputter deposition process. The plasma enhanced and the sputter deposition processes can be performed in the same IPVD chamber.

As illustrated in FIG. 4, when performing a plasma enhanced deposition process to deposit a metal film, a first precursor containing gas composition can be introduced into the processing chamber, and the first precursor containing gas composition can include a film precursor that contains a metallic compound, Subsequently, a second precursor containing gas composition can be introduced into the processing chamber, and the second precursor containing gas composition can include a reduction gas, Alternatively, a second precursor containing gas composition may not be required,

In some embodiments, a plasma can be created before, during, and or after the second precursor containing gas composition is introduced into the processing chamber to enhance the formation of the metal film. In alternate embodiments, a plasma can be created before, during, and or after the first precursor containing gas composition is introduced into the processing chamber to enhance the formation of the metal film.

In some embodiments, a purging gas can be introduced into the processing chamber before, and/or after a precursor containing gas composition is introduced into the processing chamber. In alternate embodiments, another process gas such as an inert gas may be introduced into the processing chamber before, during, and/or after a precursor containing gas composition is introduced into the processing chamber.

In some embodiments, one or more shields can be used to establish a first process space/volume in the processing chamber before, during, and/or after the first precursor containing gas composition is introduced, and the one or more shields can be used to establish a second process space/volume in the processing chamber before, during, and/or after the second precursor containing gas composition is introduced. In alternate embodiments, a process space/volume may be created by sealing one or more shields to each other.

In one embodiment, the second precursor-containing gas composition can be introduced concurrent with or immediately about the time in which the process space is increased in volume from a first volume to a second volume.

In some thermally-activated ALD processes, the deposition process can comprise sequentially and alternatingly introducing the film precursor and the reduction gas. In some thermally-activated CVD processes, the deposition process can comprise concurrent introduction of the film precursor and the reduction gas.

For instance, during a first portion of a PEALD process, the film precursor can be introduced to the processing chamber 10 to cause adsorption of the film precursor to exposed surfaces of substrate 25. Preferably, one or more monolayers of material adsorbs to the exposed substrate surfaces. During a second portion of the PEALD process, the reduction gas is introduced to processing chamber 10 to reduce the adsorbed film precursor in order to leave the desired film on substrate 25. By creating a plasma, the film creation process is enhanced. The introduction of the film precursor and the reduction gas can be repeated in order to produce a film of a desired thickness. A purge gas may be introduced between introduction of the film precursor and the reduction gas. A purge gas may be introduced before the introduction of the film precursor and/or after the introduction of the reduction gas. The purge gas can include an inert gas, such as a noble gas (i.e., helium, neon, argon, xenon, krypton).

In some PEALD processes, the first film can be deposited by sequentially and alternatingly introducing one or more film precursors and one or more reduction components, while coupling power to processing chamber 10 to form plasma during the introduction of the reduction components. In some PECVD processes, the first film can be deposited by the concurrent introduction of one or more film precursors and one or more reduction components, while coupling power to processing chamber 10 to form plasma.

When a plasma-enhanced process is performed using IPVD system (1, 1′), a plasma can be created by providing RF power to process space (85, 85′). For example, during plasma formation, power can be coupled through antenna 52 in the upper assembly 30 from the first power source 50 to the material in process space (85, 85′). The coupling of power to the material heats the material, thus causing ionization and dissociation of at least a portion of the material in order to form a deposited layer. For example, the material can include components from a first precursor-containing gas composition, or components from a second precursor-containing gas composition, or by-products of a reaction between one or more components from a first precursor-containing gas composition and one or more components from a second precursor-containing gas composition.

As shown in FIG. 4, the process space (85, 85′) and/or the interior portion of the processing chamber 10 can be purged with a purge gas for another period of time.

In 360, a query can be performed to determine when an additional layer is required. When an additional layer is not required, procedure 300 continues to 370, and when an additional layer is required, procedure 300 branches back to 330, and procedure 300 continues as shown in FIG. 3. For example, one or more processes may be performed one or more times.

The processed state of the substrate can be determined when a single substrate is being processed or when a group (lot/batch) of substrates is being processed. Alternatively, the processes state of the substrate may be determined after a single substrate is processed, or after a group (lot/batch) of substrates is processed. When the processed state is equal to a first state, an additional process can be performed on the substrate, and when the processed state is equal to a second state, an additional process is not required.

In 370, the processed substrate can be removed from the processing chamber. Procedure 300 can end in 380.

In one example, when depositing multiple tantalum containing films, a first deposition process such as a thermal ALD or thermal CVD process can be utilized to deposit a first film comprising Ta(C)N, and a second deposition process such as a plasma enhanced ALD process can be utilized to deposit a second film comprising Ta atop the first film.

In the examples given above for forming various material layers, the material deposited using the IPVD process shown in FIG. 3 can include at least one of a metal film, a metal nitride film, a metal carbonitride film, a metal oxide film, or a metal silicate film. In addition, the material deposited using the plasma-enhanced deposition process can include another material film of either the same or different metal composition. For example, the material deposited for the IPVD process shown in FIG. 3 can include at least one of a tantalum film, a tantalum nitride film, or a tantalum carbonitride film. In addition, the material deposited using the plasma-enhanced process depicted in FIG. 3 can include for example another tantalum film, another tantalum nitride film, or another tantalum carbonitride film (e.g., a tantalum film deposited over a tantalum carbonitride film).

In addition, for example, the material deposited for the IPVD process and/or the plasma-enhanced process depicted in FIG. 3 can include for example a Ru film, or a Cu film deposited to metallize a via for connecting one metal line to another metal line or for connecting for example a metal line to source/drain contacts of a semiconductor device. The Ru or Cu films can be formed with or without a plasma process using precursors for the Ru and Cu as described above.

In some embodiments, a plasma-enhanced process can be used to deposit a first material, and an IPVD process can be performed to deposit a second material. For example, a plasma-enhanced process can be used to deposit one or more Ta-containing layers, and an IPVD process can be performed to deposit one or more Cu-containing layers on top of the Ta-containing layers. In a second example, a plasma-enhanced process can be used to deposit one or more Ru-containing layers, and an IPVD process can be performed to deposit one or more Cu-containing layers on top of the Ru-containing layers. In other examples, an IPVD process can be used to perform a copper dry-filling procedure for features having a Ruthenium barrier and/or seed layer in them. Ru-containing layer can be produced using PECVD or PEALD techniques.

In other embodiments, an IPVD process can be used to deposit a first material, and a plasma-enhanced process can be used to deposit a second material. For example, an IPVD process can be used to deposit one or more Ta-containing layers, and a plasma-enhanced process can be performed to deposit one or more Ru-containing layers on top of the Ta-containing layers.

In additional embodiments, a plasma-enhanced process can be used to deposit a first material; an IPVD process can be performed to deposit a second material; and a second IPVD process can be performed to deposit a third material. For example, a plasma-enhanced process can be used to deposit one or more Ta-containing layers; an IPVD process can be performed to deposit one or more Ru-containing layers on top of the Ta-containing layers; and a second IPVD process can be performed to deposit one or more Cu-containing layers on top of the Ru-containing layers. In other examples, an IPVD process can be used to perform a dry-filling procedure for copper.

In other additional embodiments, an IPVD process can be used to deposit a first material; a plasma-enhanced process can be performed to deposit a second material; and a second IPVD process can be performed to deposit a third material. For example, an IPVD process can be used to deposit one or more Ta-containing layers; a plasma-enhanced process can be performed to deposit one or more Ru-containing layers on top of the Ta-containing layers; and a second IPVD process can be performed to deposit one or more Cu-containing layers on top of the Ru-containing layers. In other examples, an IPVD process can be used to perform a dry-filling procedure for copper.

Furthermore, an IPVD process can be used to perform an oxidation and/or a nitridation procedure on a Ru layer; next a second IPVD process can be performed to deposit an ultra-thin copper seed layer onto the modified Ru layer; and then an IPVD process can be used to perform a dry-filling procedure for copper.

As illustrated in FIG. 3, following the deposition of the first film, the second film is deposited preferably with a plasma process. A plasma process such as a plasma enhanced chemical vapor deposition (PECVD) process or a plasma enhanced atomic layer deposition process is preferred for the deposition of the second film due to its typically higher growth rate compared to thermal CVD or thermal ALD, respectively. However, other techniques can be used according to the present invention to deposit the second film.

Referring again to FIG. 4, during an alternating process, the volume of the process space (85, 85′) can be established at a first volume during introduction of the first precursor-containing gas composition (i.e. during the first time period). In addition, the volume can be changed during the introduction of the purge gas (i.e. during the second time period). The second volume can be used during the introduction of the second precursor-containing gas composition (i.e. during the third period of time). Furthermore, the volume can be changed from the second volume to the first volume during the introduction of the second purge gas (i.e. during the fourth time period). An optimal volume for the first volume and the second volume can be selected for the process space for each process step in the plasma-enhanced process.

For example, the first volume can be sufficiently small such that the first precursor-containing gas composition passes through the process space (85, 85′), and some fraction of the first precursor-containing gas composition adsorbs on the surface of the substrate. As the first volume of the process space is reduced, the amount of the first precursor-containing gas composition necessary for adsorption on the substrate surface is reduced and the time required to exchange the first precursor-containing gas composition within the first process space is reduced. For instance, as the first volume of the process space is reduced, the residence time is reduced, hence, permitting a reduction in the first period of time. Moreover, for example, the second volume can be set to a volume in which the formation of plasma from the second precursor-containing gas composition leads to the formation of uniform plasma above the substrate. Furthermore, when a plasma is being used, the substrate holder can be translated to a position that is determined to optimize the uniformity of plasma above the substrate. For example, the substrate holder can be set to a position in which the plasma uniformity is better than 2% across a 300 mm diameter of the substrate holder or better than 1% across a 300 mm diameter of the substrate holder.

The IPVD systems (1, 1′) of the present invention have been designed to perform IPVD and plasma-enhanced processes using the same processing chamber. Multiple processes can be performed in one processing chamber without the need to transfer the process substrate between different processing systems, thereby saving process time and reducing surface contamination at the interfaces between the process films, leading to improved material properties for the resultant films.

In other embodiments of the present invention, one or more cleaning processes may be performed. For example, target cleaning processes may be performed before and/or after an IPVD process is performed. In addition, chamber cleaning processes may be performed before and/or after a deposition process to remove contaminants from the processing chamber. For example, wafer-less cleaning steps may be performed after a wafer is processed and/or after a wafer lot is processed. The process gas system can provide the process gasses required during a cleaning process. In addition, the process chamber walls may be heated in order to facilitate a chemical reaction to remove the contaminants.

Although only certain exemplary embodiments of inventions have been described in detail above, those skilled in the art will readily appreciate that many modifications are possible in the exemplary embodiments without materially departing from the novel teachings and advantages of this invention.

What is claimed is:

1. A method for performing multiple material depositions on a substrate using an Ionized Physical Vapor Deposition (IPVD) system, comprising:
positioning the substrate on a substrate holder in a processing chamber of the IPVD system, the processing chamber having a first process space defined above the substrate;
determining an in-coming state for the substrate; and either
depositing an IPVD layer using an IPVD process when the in-coming state is equal to a first state or depositing a plasma-enhanced layer using a plasma-enhanced process when the in-coming state is equal to a second state.

2. The method as claimed in claim 1, further comprising:
determining a processed state for the substrate; and either
depositing an additional layer when the processed state is equal to a first state, or removing the substrate from the processing chamber when the processed state is equal to a second state.

3. The method of claim 1, wherein the depositing a layer using a plasma-enhanced process comprises:
introducing a first precursor-containing gas composition to the first process space according to a first plasma enhanced process recipe, wherein a first precursor material is deposited on the substrate;
changing the first process space to a second process space;
introducing a second precursor-containing gas composition to the second process space according to a second plasma enhanced process recipe, wherein a second precursor material is deposited on top of the first precursor material;
generating a plasma by providing RF power to an antenna coupled to the second process space during the introduction of the second precursor-containing gas, thereby accelerating a reduction reaction between the first precursor material and second precursor material at a surface of the substrate; and
forming the layer on the substrate by alternatingly introducing the first precursor-containing gas and the second precursor-containing gas.

4. The method of claim 3, wherein the first precursor-containing gas composition comprises TaF₅, TaCl₅, TaBr₅, TaI₅, Ta(CO)₅, Ta[N(C₂H₅CH₃)]₅ (PEMAT), Ta[N(CH₃)₂]₅ (PDMAT), Ta[N(C₂H₅)₂]₅ (PDEAT), Ta(NC(CH₃)₃)(N(C₂H₅)₂)₃ (TBTDET), Ta(NC₂H₅)(N(C₂H₅)₂)₃, Ta(NC(CH₃)₂C₂H₅)(N(CH₃)₂)₃, or Ta(NC(CH₃)₃)(N(CH₃)₂)₃, or a combination thereof.

5. The method of claim 3, wherein the second precursor-containing gas composition comprises H₂, NH₃, (N₂ and H₂), N₂H₄, NH(CH₃)₂, or N₂H₃CH₃, or a combination thereof.

6. The method of claim 3, wherein the first precursor-containing gas composition comprises TiF₄, TiCl₄, TiBr₄, TiI₄, Ti[N(C₂H₅CH₃)]₄ (TEMAT), Ti[N(CH₃)₂]₄ (TDMAT), or Ti[N(C₂H₅)₂]₄ (TDEAT), or a combination thereof.

7. The method of claim 3, wherein the second precursor-containing gas composition comprises H₂, NH₃, (N₂ and H₂), N₂H₄, NH(CH₃)₂, or N₂H₃CH₃, or a combination thereof.

8. The method of claim 3, wherein the first precursor-containing gas composition comprises WF₆, or W(CO)₆ or a combination thereof.

9. The method of claim 3, wherein the second precursor-containing gas composition comprises H₂, NH₃, (N₂ and H₂), N₂H₄, NH(CH₃)₂, or N₂H₃CH₃, or a combination thereof.

10. The method of claim 3, wherein the first precursor-containing gas composition comprises Ru3(CO)12, (2,4-dimethylpentadienyl)(ethylcyclopentadienyl) ruthenium (Ru(DMPD)(EtCp)), bis(2,4-dimethylpentadienyl) ruthenium (Ru(DMPD)2), or (2,4-dimethylpentadienyl) (methylcyclopentadienyl) ruthenium W(CO)₆ or a combination thereof.

11. The method of claim 3, wherein the second precursor-containing gas composition comprises H₂, NH₃, (N₂ and H₂), N₂H₄, NH(CH₃)₂, or N₂H₃CH₃, or a combination thereof.

12. The method of claim 3, wherein the first precursor-containing gas composition comprises Cu(TMVS)(hfac), or CuCl, or a combination thereof.

13. The method of claim 3, wherein the second precursor-containing gas composition comprises H₂, O₂, N₂, NH₃, or H₂O or a combination thereof.

14. The method of claim 3, wherein the changing the first process space to a second process space includes moving the substrate holder.

15. The method of claim 2, further comprising:
depositing a first IPVD layer using an IPVD process when the in-coming state is equal to a first state; and
depositing a first additional layer as a first plasma-enhanced layer using a plasma-enhanced process when the processed state is equal to the first state.

16. The method of claim 15, wherein the first IPVD layer comprises a Cu-containing material, and the first additional layer comprises a Cu-containing material.

17. The method of claim 15, wherein the first IPVD layer comprises a Ti-containing material, and the first additional layer comprises a Ti-containing material.

18. The method of claim 15, wherein the first IPVD layer comprises a Ta-containing material, and the first additional layer comprises a Ta-containing material.

19. The method of claim 15, wherein the first IPVD layer comprises a Ru-containing material, and the first additional layer comprises a Ru-containing material.

20. The method of claim 15, wherein the first IPVD layer comprises a W-containing material, and the first additional layer comprises a W-containing material.

21. The method of claim 15, wherein the first IPVD layer comprises a Ta-containing material, and the first additional layer comprises a Ru-containing material.

22. The method of claim 15, further comprising:
depositing a second additional layer as a second plasma-enhanced layer using a plasma-enhanced process when the processed state is equal to the first state.

23. The method of claim 15, further comprising:
depositing a second additional layer as a second IPVD layer using an IPVD process when the processed state is equal to the first state.

24. The method of claim 15, further comprising:
performing a dry-filling process before removing the substrate from the processing chamber.

25. The method of claim 2, further comprising:
depositing a first plasma-enhanced layer using a plasma-enhanced process when the in-coming state is equal to a first state; and
depositing a first additional layer as a first IPVD layer using an IPVD process when the processed state is equal to the first state.

26. The method of claim 25, wherein the first plasma-enhanced layer comprises a Cu-containing material, and the first additional layer comprises a Cu-containing material.

27. The method of claim 25, wherein the first plasma-enhanced layer comprises a Ti-containing material, and the first additional layer comprises a TiRu-containing material.

28. The method of claim 25, wherein the first plasma-enhanced layer comprises a Ta-containing material, and the first additional layer comprises a Ta-containing material.

29. The method of claim 25, wherein the first IPVD layer comprises a Ru-containing material, and the first additional layer comprises a Ru-containing material.

30. The method of claim 25, wherein the first plasma-enhanced layer comprises a W-containing material, and the first additional layer comprises a W-containing material.

31. The method of claim 25, wherein the first plasma-enhanced layer comprises a Ta-containing material, and the first additional layer comprises a Ru-containing material.

32. The method of claim 25, further comprising:
depositing a second additional layer as a second plasma-enhanced layer using a plasma-enhanced process when the processed state is equal to the first state.

33. The method of claim 25, further comprising:
depositing a second additional layer as a second IPVD layer using an IPVD process when the processed state is equal to the first state.

34. The method of claim 25, further comprising:
performing a dry-filling process before removing the substrate from the processing chamber.

35. The method of claim 25, further comprising:
performing a cleaning process after removing the substrate from the processing chamber.

36. The method of claim 15, further comprising:
performing a cleaning process after removing the substrate from the processing chamber.

37. An Ionized Physical Vapor Deposition (IPVD) system for performing multiple material depositions on a substrate, the IPVD system comprising:
means for positioning the substrate on a substrate holder in a processing chamber of the IPVD system, the processing chamber having a first process space defined above the substrate;
means for determining an in-coming state for the substrate;
means for depositing an IPVD layer using an IPVD process when the in-coming state is equal to a first state; and
means for depositing a plasma-enhanced layer using a plasma-enhanced process when the in-coming state is equal to a second state.

38. The IPVD system as claimed in claim 37, further comprising:
means for determining a processed state for the substrate;
means for depositing an additional layer when the processed state is equal to a first state; and
means for removing the substrate from the processing chamber when the processed state is equal to a second state.

39. The IPVD system as claimed in claim 37, further comprising:
means for introducing a first precursor-containing gas composition to the first process space according to a first plasma enhanced process recipe, wherein a first precursor material is deposited on the substrate;
means for changing the first process space to a second process space;
means for introducing a second precursor-containing gas composition to the second process space according to a second plasma enhanced process recipe, wherein a second precursor material is deposited on top of the first precursor material;
means for generating a plasma by providing RF power to an antenna coupled to the second process space during the introduction of the second precursor-containing gas, thereby accelerating a reduction reaction between the first precursor material and second precursor material at a surface of the substrate; and
means for forming the layer on the substrate by alternatingly introducing the first precursor-containing gas and the second precursor-containing gas.

40. The IPVD system as claimed in claim 37, wherein:
the means for determining an in-coming state for the substrate includes sensing means for measuring or inspecting the substrate to arrive at the determination and a controller for selecting means for depositing a layer on the substrate in response to the determination.

41. The IPVD system as claimed in claim 37, wherein:
the means for determining an in-coming state for the substrate includes means for processing data relating to the state of the substrate to arrive at the determination and a controller for selecting means for depositing a layer on the substrate in response to the determination.

42. The method as claimed in claim 1, wherein:
the determining of an in-coming state for the substrate includes automatically measuring or inspecting the substrate to arrive at the determination and selecting with a controller a process for depositing a layer on the substrate in response to the determination.

43. The IPVD system as claimed in claim 1, wherein:
the determining an in-coming state for the substrate includes retrieving and processing data relating to the state of the substrate to arrive at the determination and selecting with a controller a process for depositing a layer on the substrate in response to the determination.
